(19) United States
(12) Patent Application Publication
(10) Pub. No.: US 2001/0026007 A1
(43) Pub. Date: Oct. 4, 2001

(54) Semiconductor device with light shielding metal film

(75) Inventor: Masakazu Kagitani, Tokyo (JP)

Correspondence Address: LAFF, WHITESEL, CONTE & SARET, 401 North Michigan Avenue, Chicago, IL, 60611, US

(73) Assignee: NEC Corporation

(21) Appl. No.: 09/819,372

(22) Filed: Mar. 28, 2001

(30) Foreign Application Priority Data
Mar. 28, 2000 (JP) 2000-089443

(51) Int. Cl. H01L 23/552; H01L 21/301; H01L 21/46

(52) U.S. Cl. 257/659; 438/460; 438/928

(57) ABSTRACT

A light shielding thin metal film is formed over one or back surface of a semiconductor wafer. Material of the film includes aluminum (Al) and gold (Au).

### BACKGROUND OF THE INVENTION

1. Field of the Invention

The present invention relates to a semiconductor device, and more particularly to a semiconductor device fit for bear-chip mounting.

2. Description of the Related Art

Semiconductor devices fabricated by bear-chip mounting are used in environments that are subject to the influence of external noise. In the case where an electroluminescent (EL) diode is adjacent to a printed board, a semiconductor device receives energy as high as around 1 eV of visible radiation from the EL diode. This causes release of electrons. The release of electrons has influences on circuit operation of bear Chips. To shield light, it has been proposed to coat a back surface of a chip with resin or to attach a tape to the back surface during fabrication. Additional work required to practice this proposal causes an increase in cost and a reduction in efficiency.

JP-A 11-297903 shows a technique to shield light, According to the known technique, a back surface of a chip is covered with a polyimide resin to prevent incident of light by using dark brown color of polyimide, or a silicon substrate is made black to prevent incident of light.

Radiation of light excites electron and hole of semiconductor if its energy exceeds energy band gap of the semiconductor. Use of black silicon substrate is not effective to shield light if its energy exceeds the energy band. Use of resin needs to cope with instability of resin as material and an increase in package size. Covering a chip with resin makes it difficult for the chip to release heat, lowering the amount of heat released through the exposed back surface of the chip. Polishing work to provide a resin film of uniform thickness and to reduce thickness of the film involves the possibility of breaking the chip. Accordingly, a need remains toward development of a protective film with effective light shielding, which is easy to deposit as a film without applying any great stress to a chip and without any drop in merits of bear chip and chip size package.

Accordingly, an object of the present invention is to provide a semiconductor device fabricated by bear-chip mounting, which semiconductor device is capable of shielding light noise without any shortcomings of the conventional device mentioned above.

### SUMMARY OF THE INVENTION

According to one exemplary implementation of the invention, there is provided a semiconductor device comprises:

a semiconductor wafer having a surface; and

a light shielding metal film formed over the surface.

According to another exemplary implementation of the invention, there is provided a semiconductor device comprising:

a semiconductor chip having a surface; and

a light shielding metal film formed over the surface.

### BRIEF DESCRIPTION OF THE DRAWINGS

The foregoing and other objects, features and advantages of the invention will be apparent from the following more particular description of exemplary embodiments of the invention as illustrated in the accompanying drawings, The drawings are not necessarily scale, emphasis instead being placed upon illustrating the principles of the invention.

FIG. 1 illustrates a cross-sectional view of a first embodiment of a semiconductor device according to the present invention.

FIG. 2 illustrates a cross-sectional view of a second embodiment of a semiconductor device according to the present invention.

FIG. 3 illustrates a flow chart of the first embodiment of the present invention.

FIG. 4 illustrates a process of the flow chart.

FIG. 5 illustrates a process after the process of FIG. 4.

FIG. 6 illustrates a process after the process of FIG. 5.

FIG. 7 illustrates a process after the process of FIG. 6.

FIG. 8 illustrates a flow chart of the second embodiment of the present invention.

FIG. 9 illustrates a process of the flow chart of FIG. 8.

FIG. 10 illustrates a process after the process of FIG. 9.

FIG. 11 illustrates a process after the process of FIG. 10.

FIG. 12 illustrates a process after the process of FIG. 11.

### DESCRIPTION OF THE PREFERRED EMBODIMENT

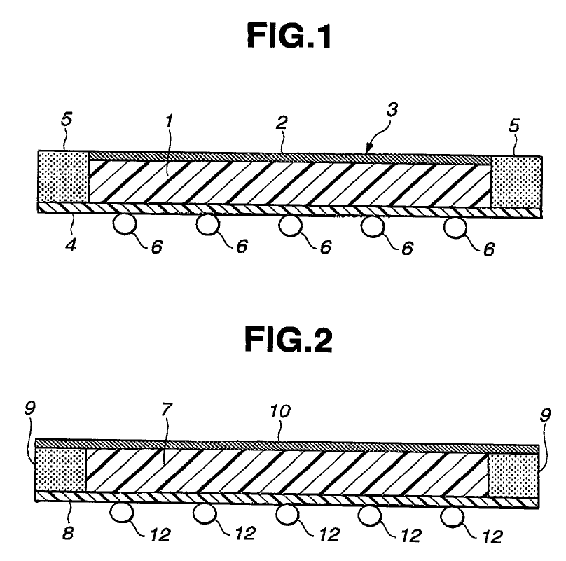

Referring to the accompanying drawings, the same reference numerals are used to designate same or similar parts or portions throughout FIGS. 1, 3-7. or throughout FIGS. 2, 8-12 for the sake of brevity of description.

In preferred implementation of the present invention, a semiconductor device is provided with a protective film for shielding light noise. The semiconductor device has a back surface exposed, which is found in a semiconductor device fit for bear-chip mounting or in a semiconductor device of a chip size package.

Radiation of photon excites electron and hole of a semiconductor device if its energy exceeds energy band gap of material of the semiconductor device. If the material is silicon (Si), radiation of photon with energy level exceeding around 1 eV will cause excitation of electron and hole. Electron and hole cause malfunction of circuit of the bear chip. In order to shield radiation of such energy, that is, light having wave lengths not longer than a certain wave length, the present invention provides a light shielding metal film 2 (in FIG. 1) or 10 (in FIG. 2) deposited by sputtering or metal paste. With the light shielding metal film, light is reflected, thus ensuring shielding of light noise.

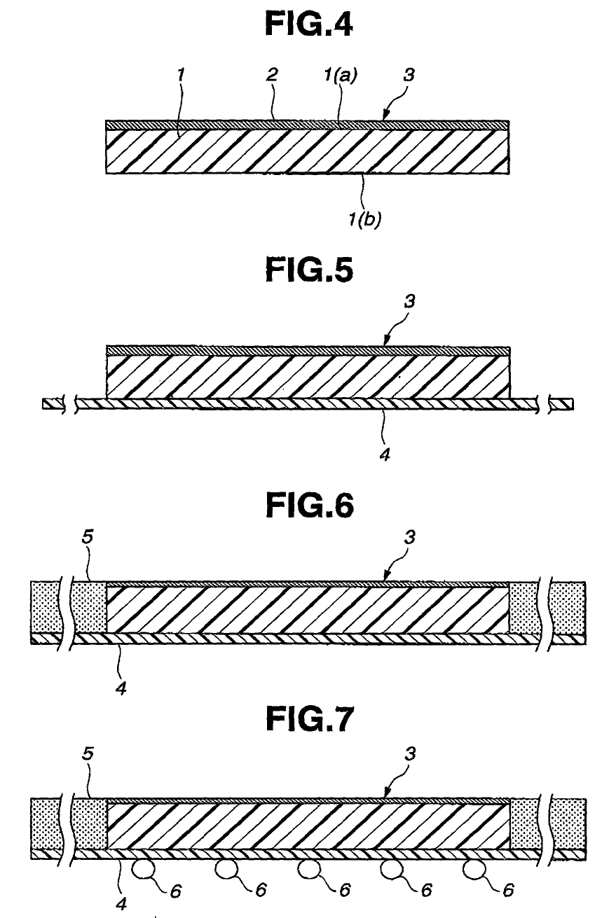

FIGS. 1, 3-7 illustrate a first preferred embodiment of a semiconductor device according to the present invention. The reference numeral 1 indicates a semiconductor wafer with a light shielding metal (LSM) thin film 2. In the embodiment, the LSM film 2 is formed over substantially the whole area of one or back surface l(a) of the wafer 1 (see FIG. 4).

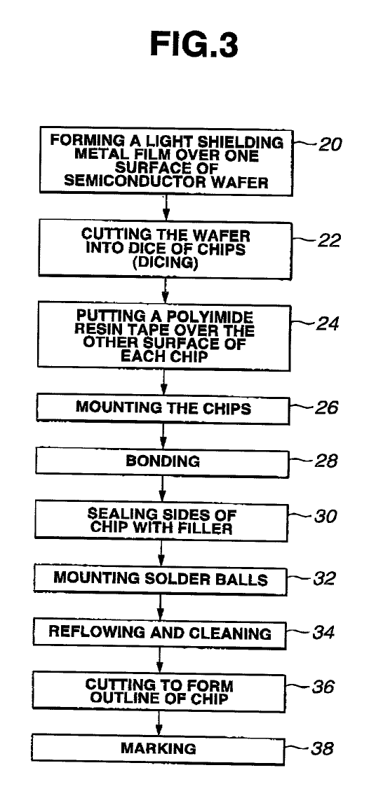

LSM film 2 is formed over back surface 1(a) of wafer 1 that has been subject to back surface grinding. Subsequently, wafer 1 with LSM film 2 is subject to various processing steps as illustrated in FIG. 3 to fabricate chip size semiconductor devices.

After diffusion, a wafer thinned by back surface grinding is subject to back surface sputtering using a generally known apparatus for sputter deposition. The sputtered material is deposited on a back surface of wafer 1 to form a thin film having several micron meters (μm) thick. This film serves as a protective film capable of shielding light. Chemical vapor deposition (CVD) or vapor deposition may be used instead of sputtering. However, the use of sputtering is advantageous in that little chemical reaction is required. Sputtered material includes aluminum (Al) and gold (Au). It is known that if used as sputtered material to deposit, metal having a high melting point provides high stress in the deposited thin film, which is thus fragile. Besides, aluminum and gold remain chemically stable. Carrying out sputtering at temperature not lower than 350° C. can prevent any change in composition of materials because the subsequent processes are carried out within temperature environment ranging from 210° C. to 350° C.

Flow chart of FIG. 3 illustrates fabrication steps in chip size package. In step 20, sputtered material of aluminum or gold is deposited on a back surface 1(a)of a semiconductor wafer 1 to form a light shielding metal (LSM) thin film 2. In step 22, wafer 1 is cut into dice or chips (dicing), one of which is generally indicated at 3 in FIG. 4. In FIG. 4, the reference numeral 1(b) indicates a front surface that is patterned. In the next step 24, a polyimide resin tape 4 is put over the front surface 1(b) of the chip 3 as illustrated in FIG. 5. Under load of around 250 g at temperature of around 300° C., the polyimide resin tape 4 is adhered to the surface 1(b). The polyimide resin tape 4 has an electrical wiring for solder balls 6. In step 26, several tens of chips are mounted to a tape attached to a carrier frame. In step 28, the chips are bonded to the tape of the carrier frame. In step 30, lateral sides of each chip 3 between the back and front surfaces 1(a) and 1(b) are sealed for reinforcing the Chip 3 as illustrated in FIG. 6. In FIG. 6, filler resin 5 is cured after having flown into contact with the lateral sides of chip 3 on polyimide resin tape 4.

In the next step 32, solder balls 6 are mounted to polyimide resin tape 4 as illustrated in FIG. 7. Flux is attached to solder balls 6 drawn to a mold before mounting the balls 6 onto the polyimide resin tape 4. In step 34, reflowing and cleaning are carried out. In step 36, cutting is carried out to form outline of each chip. In step 38, a laser marking is carried out. In each of the steps, high temperature baking or cleaning may be carried out if appropriate for maintaining material stability. Upon completion of these steps, the chip as illustrated in FIG. 1 is given.

The above description has focused on metal sputtering as a measure to form a LSM thin film 2. Other measures or metal materials may be used to form a LSM thin film as long as the formed thin film is capable of shielding light and conducting heat.

FIGS. 2, 8-12 illustrate a second preferred embodiment of a semiconductor device according to the present invention. As different from the first embodiment, a LSM thin film 10 is formed during fabrication of bear chips.

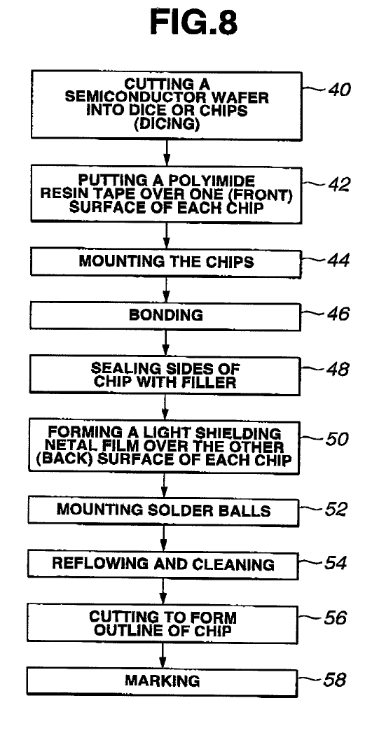

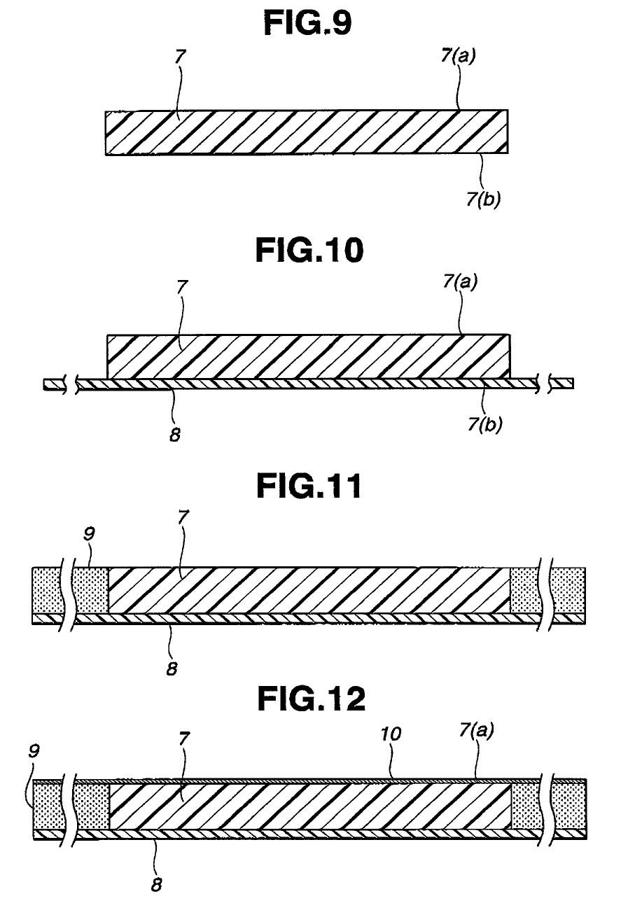

Flow chart of FIG. 8 illustrates fabrication steps in chip size package. In step 40, a wafer is cut into dice or chips (dicing), one of which is generally indicated at 7 in FIG. 9. In FIG. 9, the reference numeral 7(a) indicates a back surface, and the reference numeral 7(b) indicates a front surface that is patterned. In the next step 42, a polyimide resin tape 8 is put over the front surface 7(b) of the chip 7 as illustrated in FIG. 10. Under load of around 250 g at temperature of around 300° C., the polyimide resin tape 8 is adhered to the surface 7(b). In step 44, several tens of chips are mounted to a tape attached to a carrier frame. In step 46, the chips are bonded to the tape of the carrier frame. In step 48, lateral sides of each chip 7 between the back and front surfaces 7(a) and 7(b) are sealed for reinforcing the chip 7 as illustrated in FIG. 11. In FIG. 11, filler resin 9 is cured after having flown into contact with the lateral sides of chip 7 on polyimide resin tape 8.

In step 50, a light shielding metal (LSM) thin film 10 having several micron meters to several tens micron meters thick are formed over the back surface 7(a) by paste. Particles having a grain size of around 1 micron meter aresprayed onto the back surface 7(a) of chip 7. The material of LSM thin film 10 include aluminum (Al) or gold (Au).

In the next step 52, solder balls are mounted to polyimide resin tape 8. In step 54, reflowing and cleaning are carried out. In step 56, cutting is carried out to form outline of each chip. In step 58, a laser marking is carried out. Upon completion of these steps, the chip as illustrated in FIG. 2 is given.

The LSM thin film 10 forming step 50 is located after sealing step 48 and before solder balls mounting step 52. This is advantageous in that the material used as paste will not be adhered to the chip surface, circuit on the tape or balls.

Provision of LSM thin film 2 and 10 is advantageous in that light is shielded, and high heat conductive of metal forming the thin film ensures release of heat through the back surface 1(a) and 7(a).

While the present invention has been particularly described, in conjunction with preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

What is claimed is:

1. A semiconductor device comprises:
a semiconductor wafer having a surface; and
a light shielding metal film formed over the surface.

2. The semiconductor device as claimed in claim 1, further comprising:
a conductor circuit on the semiconductor wafer.

3. The semiconductor device a claimed in claim 1, wherein the light shielding metal film is formed by aluminum (Al).

4. The semiconductor device a claimed in claim 1, wherein the light shielding metal film is formed by gold (Au).

5. A semiconductor device comprising:
a semiconductor chip having a surface; and
a light shielding metal film formed over the surface.

6. The semiconductor device as claimed in claim 5, further comprising:
a conductor circuit on the semiconductor chip.

7. The semiconductor device a claimed in claim 5, wherein the light shielding metal film is formed by aluminum (Al).

8. The semiconductor device a claimed in claim 5, wherein the light shielding metal film is formed by gold (Au).

9. A method of fabricating a semiconductor chip, comprising:
forming a light shielding metal film over one surface of a semiconductor wafer: and
cutting the wafer into chips.

10. A method of fabricating a semiconductor chip, comprising:
cutting a semiconductor wafer into chips; and
forming a light shielding metal film over one surface of each of the chips.
